(19) United States
(12) Patent Application Publication
(10) Pub. No.: US 2024/0282664 A1
(43) Pub. Date: Aug. 22, 2024

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Hidetoshi ISHIBASHI, Tokyo (JP); Yasutaka SHIMIZU, Tokyo (JP)

(73) Assignee: Mitsubishi Electric Corporation, Tokyo (JP)

(21) Appl. No.: 18/404,538

(22) Filed: Jan. 4, 2024

(30) Foreign Application Priority Data
Feb. 20, 2023 (JP) 2023-024212

(51) Int. Cl. H01L 23/40; H01L 23/00

(52) U.S. Cl. CPC H01L 23/4006; H01L 2023/405; H01L 2023/4068; H01L 24/32; H01L 24/48; H01L 24/73; H01L 2224/32227; H01L 2224/48091; H01L 2224/48227; H01L 2224/73265

(57) ABSTRACT

Provided is a semiconductor device that can prevent TIM pumping out while suppressing a decline in productivity. A semiconductor device includes a heat dissipation surface to which heat dissipation fins are attached, and a heat dissipation surface wire bonded to at least one location on the heat dissipation surface. An amount of protrusion of the heat dissipation surface wire from the heat dissipation surface is 10 μm or more and 200 μm or less. The heat dissipation fins are attached to the heat dissipation surface of the semiconductor device via the heat dissipation surface wire and a TIM, which is a thermal interface material.

### BACKGROUND OF THE INVENTION

### Field of the Invention

The present disclosure relates to a semiconductor device.

### Description of the Background Art

Semiconductor devices for power control called power modules, power devices, etc. are attached with a cooler such as heat dissipation fins and a heat sink via a thermal interface material (TIM). A thermal interface material (TIM) with fluidity, such as thermal grease, can efficiently transfer heat from a semiconductor device to a cooler by filling a small space between the semiconductor device and the cooler.

However, TIM with fluidity gradually flows over time, a phenomenon called “pumping out” occurs in which a TIM gradually leaks out from between the semiconductor device and the cooler. TIM pumping out invites problems such as a decline in heat dissipation property and poor insulation of the semiconductor device.

For example, International Publication No. 2021/095146 discloses a technique in which by providing irregularities on the cooler mounting surface (hereinafter referred to as “heat dissipation surface”) of semiconductor device to suppress the flow of the TIM over time, thereby preventing TIM pumping out.

As in International Publication No. 2021/095146, by providing irregularities on the heat dissipation surface of the semiconductor device, the flow of the TIM over time is suppressed, however, that requires processing of providing irregularities on the heat dissipation surface, leading to a difficulty in adjustment of the dimensions (thickness) of the semiconductor device. Further, having convex portions in a protrusion form are provided on the heat dissipation surface may become a factor that lowers productivity, in such manner as to create necessary to process a hot plate used during reflow, or to be prone to be stuck during conveyor transportation.

### SUMMARY

The object of the present disclosure is to provide a semiconductor device that can prevent TIM pumping out while suppressing a decline in productivity.

The semiconductor device according to the present disclosure includes a heat dissipation surface to which a cooler is attached, and a heat dissipation surface wire bonded to at least one location in the heat dissipation surface. An amount of protrusion of the heat dissipation surface wire from the heat dissipation surface is 10 μm or more and 200 μm or less.

According to the present disclosure, TIM pumping out is prevented while suppressing a decline in productivity of the semiconductor device.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view of a semiconductor device according to Embodiment 1;

FIG. 2 is a plan view of the heat dissipation surface side of the semiconductor device according to Embodiment 1;

FIG. 3 is a diagram for illustrating the problem of TIM pumping out;

FIG. 4 is a diagram for illustrating the problem of TIM pumping out;

FIG. 5 is a plan view illustrating a configuration of a semiconductor device according to Embodiment 2;

FIG. 6 is a plan view of the heat dissipation surface side of a semiconductor device according to Embodiment 3;

FIG. 7 is a cross-sectional view illustrating a state in which the PC-TIM is printed on the heat dissipation surface of the semiconductor device according to Embodiment 3;

FIG. 8 is a plan view of the heat dissipation surface side of a semiconductor device according to Embodiment 4; and

FIG. 9 is a cross-sectional view illustrating a state in which a heat dissipation sheet is attached to the heat dissipation surface of the semiconductor device according to Embodiment 4.

### DESCRIPTION OF THE PREFERRED EMBODIMENTS

### Embodiment 1

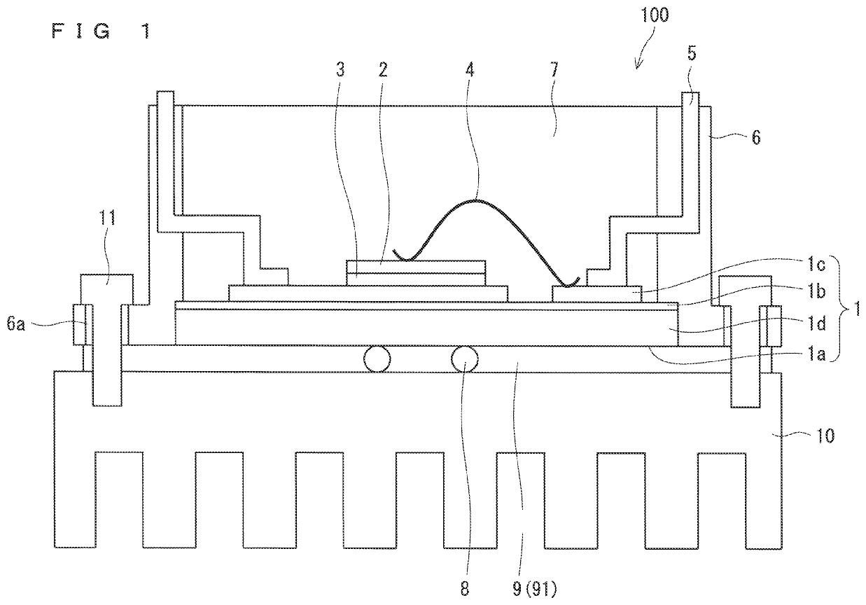

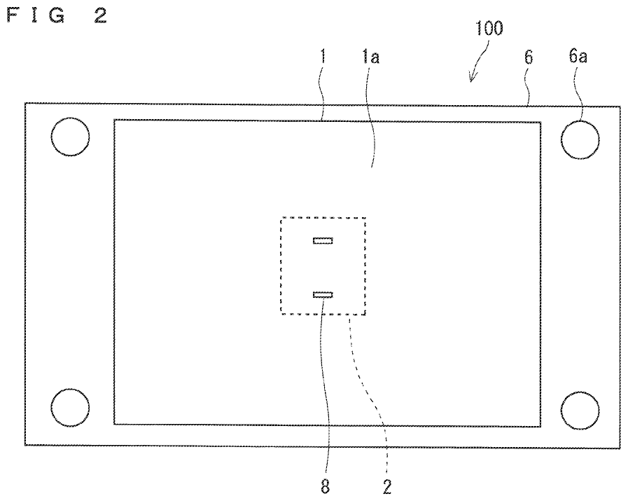

FIGS. 1 and 2 are diagrams illustrating a configuration of a semiconductor device 100 according to Embodiment 1. FIG. 1 is a cross-sectional view of the semiconductor device 100, and FIG. 2 is a plan view of the heat dissipation surface side of the semiconductor device 100.

As illustrated in FIG. 1, the semiconductor device 100 includes a base plate 1 and a semiconductor chip 2 mounted on the base plate 1. The lower surface of the base plate 1 serves as a heat dissipation surface 1a to which the heat dissipation fins 10 are attached.

In Embodiment 1, the base plate 1 includes an insulating layer 1b, a metal pattern 1c made of copper, for example, provided on the insulating layer 1b, and a metal layer 1d made of, for example, copper, provided below the insulating layer 1b. The semiconductor chip 2 is bonded onto the metal pattern 1c using solder 3.

The semiconductor chip 2 is electrically connected to an electrode 5 via a wire 4 made of metal and the metal pattern 1c, and the electrode 5 is bonded to the metal pattern 1c with solder (not illustrated) or the like, thereby forming a desired circuit.

The base plate 1 is fitted to the bottom of a case 6, and the case 6 is bonded to the outer edge of the base plate 1 with an adhesive (not illustrated). The electrode 5 is inserted into the case 6, and a portion thereof protrudes outward from the case 6 to function as a terminal for external connection. The case 6 is filled with a sealing resin 7, and the semiconductor chip 2, the wire 4, and the like, placed inside the case 6 are sealed with the sealing resin 7.

Heat dissipation fins 10, which is a cooler, is attached to the heat dissipation surface 1a of the semiconductor device 100 via a TIM 9. Attachment holes 6a am provided in the case 6, and the heat dissipation fins 10 are fixed to the heat dissipation surface 1a of the semiconductor device 100 using screws 11 inserted into the attachment holes 6a. The TIM 9 is interposed between the heat dissipation surface 1a and the heat dissipation fins 10, and efficiently transfers the heat generated in the semiconductor chip 2 to the heat dissipation fins 10.

In Embodiment 1, as the TIM 9, heat dissipation grease 91 such as silicone grease containing aluminum filler or ceramic filler is used, for example. However, the material of the TIM 9 is not limited thereto, and for example, a heat dissipation sheet such as a phase change thermal interface material, a silicone sheet, or a graphite sheet laminated with graphene may be used.

In the semiconductor device 100 according to Embodiment 1, a heat dissipation surface wire 8 is bonded to at least one location on the heat dissipation surface 1a. With the heat dissipation surface wire 8 provided on the heat dissipation surface 1a, a constant thickness of the TIM 9 can be secured, and heat dissipation tolerance is ensured against deformations such as warping in the semiconductor device 100.

The heat dissipation surface wire 8 is a metal wire made of aluminum, copper, or the like, and is bonded to the heat dissipation surface 1a. The amount of protrusion of the heat dissipation surface wire 8 from the heat dissipation surface 1a, that is, the thickness of the heat dissipation surface wire 8 between the heat dissipation surface 1a and the heat dissipation fins 10 is 10 μm or more and 200 μm or less.

In the process of forming the semiconductor device 100, the semiconductor device 100, including the heat dissipation surface 1a, is assembled, and then the heat dissipation surface wire 8, having a diameter of 10 μm or more and 400 μm or less, is bonded to the heat dissipation surface 1a by, for example, ultrasonic bonding. At this point, the thickness of the heat dissipation surface wire 8, crushed by pressure applied during ultrasonic bonding, is adjusted to be 10 μm or more and 200 μm. Alternatively, the heat dissipation surface wire 8 is bonded to the heat dissipation surface 1a, and then, the heat dissipation surface wire 8 is to be crushed to a desired thickness by pressing.

Note that the configuration of the semiconductor device 100 illustrated in FIG. 2 is a mere example. For example, the base plate 1 may be a ceramic substrate or a plate obtained by bonding a ceramic substrate onto a metal layer. The configuration of the semiconductor device 100 need only include a heat dissipation surface 1a on which a semiconductor chip 2 is mounted and to which a cooler for dissipating the heat of the semiconductor chip 2 is attached.

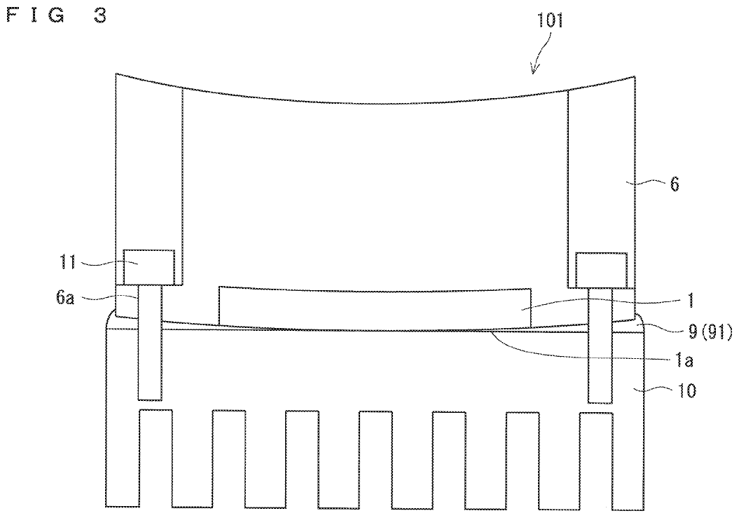

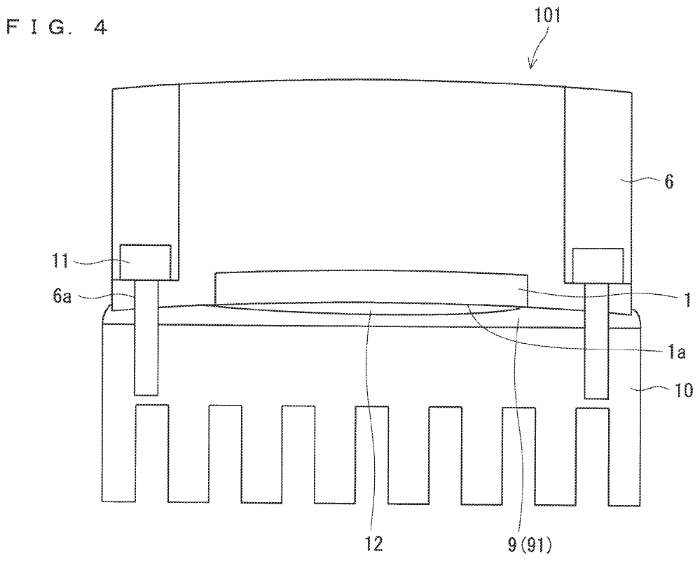

Here, the problem of TIM pumping out will be explained referring to FIGS. 3 and 4. FIGS. 3 and 4 illustrate a semiconductor device 101 as a comparative example without the heat dissipation surface wire 8, in which, for convenience of illustration, only the base plate 1 and the case 6 of the semiconductor device 101 are illustrated and the rest of the components are omitted and not illustrated.

Typically, the heat dissipation surface 1a of the semiconductor device 101 is often designed and managed in a convex shape as illustrated in FIG. 3 in order to reduce the thermal resistance between the base plate 1 and the heat dissipation fins 10. In this case, when the screws 11 for fixing are tightened to press the heat dissipation fins 10 into contact with the heat dissipation fins 10, the TIM 9 is pushed out around the semiconductor device 101, creating a portion in which the initial thickness cannot be secured.

And, when the semiconductor chip 2 generates heat during actual use, the base plate 1 warps as illustrated in FIG. 4. At this point, the portion, in which the sufficient initial thickness of the TIM 9 was unable to be secured at the time of FIG. 3, cannot follow the deformation of the base plate 1, resulted in a space formed between the semiconductor device 101 and the heat dissipation fins 10 as illustrated in FIG. 4, leading to deterioration of thermal resistance.

According to the semiconductor device 100 according to Embodiment 1, having the heat dissipation surface wire 8 interpose between the heat dissipation surface 1a and the heat dissipation fins 10 secures the initial thickness of the TIM 9; therefore, deterioration of thermal resistance due to pumping out of the TIM 9 as illustrated in FIGS. 3 and 4 can be prevented. Further, unlike the technique of International Publication No. 2021/095146, the process to make irregularities on the heat dissipation surface 1a is eliminated, which suppresses a decrease in productivity.

It is effective in particular, as illustrated in FIG. 2, the heat dissipation surface wires 8 are arranged in a manner that the heat dissipation surface wires 8 are provided at one or more locations within the region overlapping with the semiconductor chip 2, because the thickness of the TIM 9 can be surely secured in the region immediately below the semiconductor chip 2, which is effective for heat dissipation of the semiconductor chip 2.

### Embodiment 2

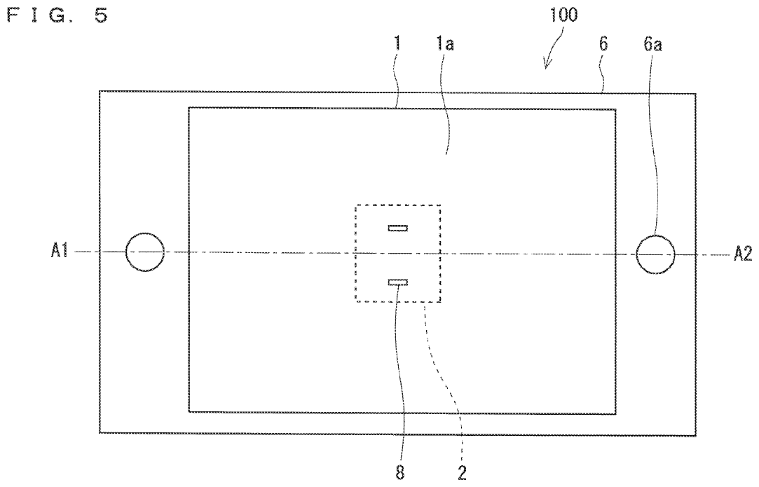

FIG. 5 is a plan view of the heat dissipation surface side of a semiconductor device 100 according to Embodiment 100. In Embodiment 2, the heat dissipation surface wires 8 are arranged so that the heat dissipation surface wires 8 are provided at one or more locations on each of both sides of the median line drawn in the longitudinal direction of the heat dissipation surface 1a (line A1-A2 in FIG. 5).

For example, as illustrated in FIG. 5, when the attachment holes 6a of the semiconductor device 100 are only at two locations on the median line drawn in the longitudinal direction of the heat dissipation surface 1a, the gap between the heat dissipation surface 1a and the heat dissipation fins 10 (that is, the thickness of the TIM 9) is likely to be unstable. However, as in Embodiment 2, by arranging the heat dissipation surface wires 8 on both sides of the median line drawn in the longitudinal direction of the heat dissipation surface 1a, the gap between the heat dissipation surface 1a and the heat dissipation fins 10 is stabilized, enabling to secure the thickness of the TIM 9 in a more stable manner.

### Embodiment 3

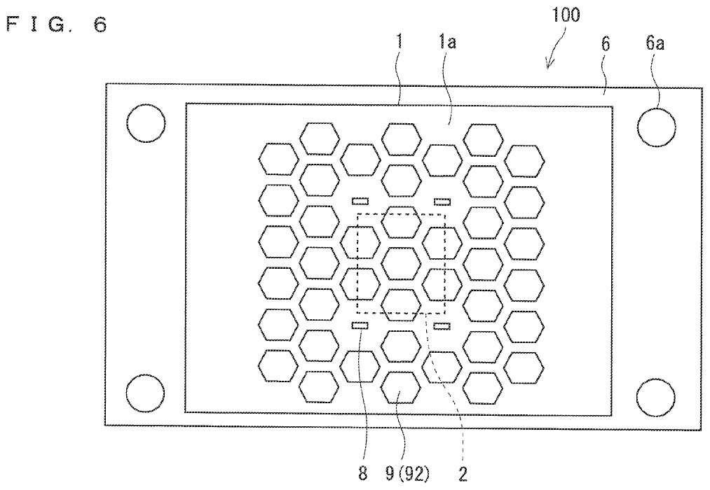

FIG. 6 is a plan view of the heat dissipation surface side of a semiconductor device 100 according to Embodiment 3. In Embodiment 3, a phase change thermal interface material (PC-TIM) is used as the TIM 9.

As illustrated in FIG. 6, a PC-TIM 92 is printed in a predetermined pattern on the heat dissipation surface 1a of the semiconductor device 100 according to Embodiment 3. In this case, the step of printing the PC-TIM 92 on the heat dissipation surface 1a is preferably performed before the step of bonding the heat dissipation surface wires 8 to the heat dissipation surface 1a. In particular, after assembling the semiconductor device 100, the PC-TIM 92 is printed on the heat dissipation surface 1a and dried, and the heat dissipation surface wires 8 are bonded to the heat dissipation surface 1a in the final step. Even when the PC-TIM 92 is used as the TIM 9, the required amount of TIM can be secured by providing the heat dissipation surface wires 8 on the heat dissipation surface 1a.

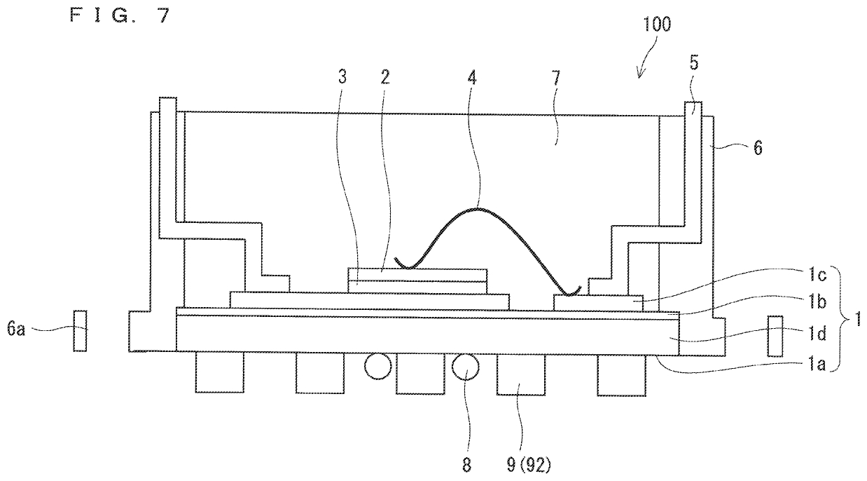

In addition, in Embodiment 3, as illustrated in FIG. 7, the thickness of the PC-TIM 92 printed on the heat dissipation surface 1a, that is, the thickness of the PC-TIM 92 before the heat dissipation fins 10 is attached to the heat dissipation surface 1a is, desirably greater than the amount of protrusion from the heat dissipation surface 1a of the heat dissipation surface wires 8 whose thickness is adjusted to be 10 μm or more and 200 μm or less. With this configuration, when the heat dissipation fins 10 are attached to the heat dissipation surface 1a, the PC-TIM 92 is crushed and spread over the entire heat dissipation surface 1a, which contributes to improving the heat dissipation property of the PC-TIM 92.

### Embodiment 4

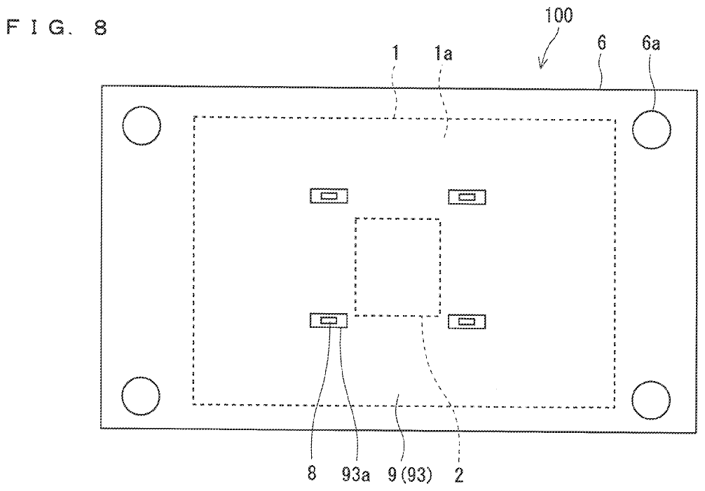

FIG. 8 is a plan view of the heat dissipation surface side of a semiconductor device 100 according to Embodiment 4. In Embodiment 4, a heat dissipation sheet 93 is used as the TIM 9.

As illustrated in FIG. 8, the heat dissipation sheet 93 is attached to the heat dissipation surface 1a of the semiconductor device 100 according to Embodiment 4. Slits 93a are provided in the heat dissipation sheet 93 at the locations corresponding to the locations of the heat dissipation surface wires 8 so that the heat dissipation sheet 93 and the heat dissipation surface wires 8 do not interfere with each other.

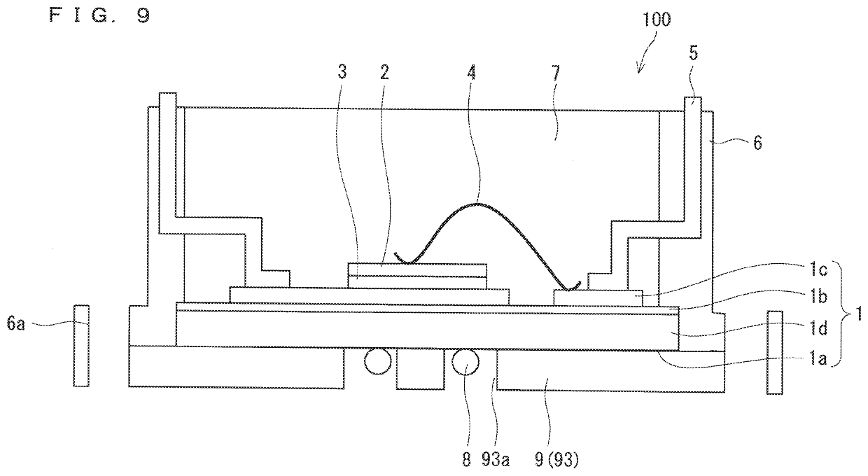

In addition, in Embodiment 4, as illustrated in FIG. 9, the thickness of the heat dissipation sheet 93 attached to the heat dissipation surface 1a, that is, the thickness of the heat dissipation sheet 93 before the heat dissipation fins 10 is attached to the heat dissipation surface 1a is, desirably greater than the amount of protrusion from the heat dissipation surface 1a of the heat dissipation surface wires 8 whose thickness is adjusted to be 10 μm or more and 200 μm or less. With this configuration, when the heat dissipation fins 10 are attached to the heat dissipation surface 1a, the screws 11 can be tightened while controlling the required thickness of the heat dissipation sheet 93.

As the heat dissipation sheet 93, for example, a filler-containing silicone sheet, a graphite sheet laminated with graphene or the like, can be used.

It should be noted that Embodiments can be arbitrarily combined and can be appropriately modified or omitted.

### <Appendix>

Hereinafter, the aspects of the present disclosure will be collectively described as Appendices.

### (Appendix 1)

A semiconductor device comprising:
a heat dissipation surface to which a cooler is attached; and
a heat dissipation surface wire bonded to at least one location in the heat dissipation surface, wherein
an amount of protrusion of the heat dissipation surface wire from the heat dissipation surface is 10 μm or more and 200 μm or less.

### (Appendix 2)

The semiconductor device according to Appendix 1, wherein
the heat dissipation surface wires are provided at one or more locations within a region overlapping with a semiconductor chip the semiconductor device includes.

### (Appendix 3)

The semiconductor device according to Appendix 1 or 2, wherein
the heat dissipation surface wires are provided at one or more locations on each of both sides of a median line drawn in a longitudinal direction of the heat dissipation surface.

### (Appendix 4)

The semiconductor device according to any one of Appendices 1 to 3, further comprising
a TIM being a thermal interface material provided on the heat dissipation surface.

### (Appendix 5)

The semiconductor device according to Appendix 4, wherein
the TIM is a PC-TIM being a phase change thermal interface material.

### (Appendix 6)

The semiconductor device according to Appendix 5, wherein
a thickness of the PC-TIM is greater than an amount of protrusion of the heat dissipation surface wire from the heat dissipation surface.

### (Appendix 7)

The semiconductor device according to Appendix 4, wherein
the TIM is a heat dissipation sheet having slits at locations corresponding to locations of the heat dissipation surface wires.

### (Appendix 8)

The semiconductor device according to Appendix 7, wherein
a thickness of the heat dissipation sheet is greater than an amount of protrusion of the heat dissipation surface wire from the heat dissipation surface.

### (Appendix 9)

The semiconductor device according to any one of Appendices 4, 5, and 7, further comprising
a cooler attached to the heat dissipation surface via the heat dissipation surface wires and the TIM.

### (Appendix 10)

10. A method of manufacturing a semiconductor device comprising the steps of:
(a) forming the semiconductor device including a heat dissipation surface to which a cooler is attached; and
(b) bonding a heat dissipation surface wire to at least one location in the heat dissipation surface, and adjusting a thickness of the heat dissipation surface wire to 10 μm or more and 200 μm or less.

### (Appendix 11)

The method of manufacturing the semiconductor device according to Appendix 10, wherein
a diameter of the heat dissipation surface wire to be bonded to the heat dissipation surface is 10 μm or more and 400 μm or less.

### (Appendix 12)

The method of manufacturing the semiconductor device according to Appendices 10 or 11, wherein
in the step (b), the heat dissipation surface wires are bonded to at one or more locations within a region overlapping with a semiconductor chip the semiconductor device includes.

### (Appendix 13)

The method of manufacturing the semiconductor device according to any one of Appendices 10 to 12, wherein
in the step (b), the heat dissipation surface wires are bonded to at one or more locations on each of both sides of a median line drawn in a longitudinal direction of the heat dissipation surface.

### (Appendix 14)

The method of manufacturing the semiconductor device according to any one of Appendices 10 to 13, further comprising the step of
(c) forming a TIM being a thermal interface material on the heat dissipation surface.

### (Appendix 15)

The method of manufacturing the semiconductor device according to Appendix 14, wherein
the step (c) includes a step of printing a PC-TIM being a phase change thermal interface material as the TIM on the heat dissipation surface.

### (Appendix 16)

The method of manufacturing the semiconductor device according to Appendix 15, wherein
a thickness of the PC-TIM printed on the heat dissipation surface in the step (c) is greater than an amount of protrusion of the heat dissipation surface wire from the heat dissipation surface after the step (b).

### (Appendix 17)

The method of manufacturing the semiconductor device according to Appendix 15 or 16, wherein
the step (c) is performed before the step (b).

### (Appendix 18)

The method of manufacturing the semiconductor device according to Appendix 14, wherein
the step (c) includes a step of attaching a heat dissipation sheet having slits at locations corresponding to locations of the heat dissipation surface wires to the heat dissipation surface as the TIM.

### (Appendix 19)

The method of manufacturing the semiconductor device according to Appendix 18, wherein
a thickness of the heat dissipation sheet attached to the heat dissipation surface in the step (c) is greater than an amount of protrusion of the heat dissipation surface wire from the heat dissipation surface after the step (b).

### (Appendix 20)

The method of manufacturing the semiconductor device according to any one of Appendices 14 to 19, further comprising the step of
(d) attaching a cooler to the heat dissipation surface via the heat dissipation surface wires and the TIM.

While the invention has been illustrated and described in detail, the foregoing description is in all aspects illustrative and not restrictive. It is therefore understood that numerous modifications and variations can be devised without departing from the scope of the invention.

What is claimed is:

1. A semiconductor device comprising:
a heat dissipation surface to which a cooler is attached; and
a heat dissipation surface wire bonded to at least one location in the heat dissipation surface, wherein
an amount of protrusion of the heat dissipation surface wire from the heat dissipation surface is 10 μm or more and 200 μm or less.

2. The semiconductor device according to claim 1, wherein
the heat dissipation surface wires are provided at one or more locations within a region overlapping with a semiconductor chip the semiconductor device includes.

3. The semiconductor device according to claim 1, wherein
the heat dissipation surface wires are provided at one or more locations on each of both sides of a median line drawn in a longitudinal direction of the heat dissipation surface.

4. The semiconductor device according to claim 1, further comprising
a TIM being a thermal interface material provided on the heat dissipation surface.

5. The semiconductor device according to claim 4, wherein
the TIM is a PC-TIM being a phase change thermal interface material.

6. The semiconductor device according to claim 5, wherein
a thickness of the PC-TIM is greater than an amount of protrusion of the heat dissipation surface wire from the heat dissipation surface.

7. The semiconductor device according to claim 4, wherein
the TIM is a heat dissipation sheet having slits at locations corresponding to locations of the heat dissipation surface wires.

8. The semiconductor device according to claim 7, wherein
a thickness of the heat dissipation sheet is greater than an amount of protrusion of the heat dissipation surface wire from the heat dissipation surface.

9. The semiconductor device according to claim 4, further comprising a cooler attached to the heat dissipation surface via the heat dissipation surface wires and the TIM.

10. A method of manufacturing a semiconductor device comprising the steps of:
(a) forming the semiconductor device including a heat dissipation surface to which a cooler is attached; and
(b) bonding a heat dissipation surface wire to at least one location in the heat dissipation surface, and adjusting a thickness of the heat dissipation surface wire to 10 μm or more and 200 μm or less.

11. The method of manufacturing the semiconductor device according to claim 10, wherein
a diameter of the heat dissipation surface wire to be bonded to the heat dissipation surface is 10 μm or more and 400 μm or less.

12. The method of manufacturing the semiconductor device according to claim 10, wherein
in the step (b), the heat dissipation surface wires are bonded to at one or more locations within a region overlapping with a semiconductor chip the semiconductor device includes.

13. The method of manufacturing the semiconductor device according to claim 10, wherein
in the step (b), the heat dissipation surface wires are bonded to at one or more locations on each of both sides of a median line drawn in a longitudinal direction of the heat dissipation surface.

14. The method of manufacturing the semiconductor device according to claim 10, further comprising the step of
(c) forming a TIM being a thermal interface material on the heat dissipation surface.

15. The method of manufacturing the semiconductor device according to claim 14, wherein
the step (c) includes a step of printing a PC-TIM being a phase change thermal interface material as the TIM on the heat dissipation surface.

16. The method of manufacturing the semiconductor device according to claim 15, wherein
a thickness of the PC-TIM printed on the heat dissipation surface in the step (c) is greater than an amount of protrusion of the heat dissipation surface wire from the heat dissipation surface after the step (b).

17. The method of manufacturing the semiconductor device according to claim 15, wherein
the step (c) is performed before the step (b).

18. The method of manufacturing the semiconductor device according to claim 14, wherein
the step (c) includes a step of attaching a heat dissipation sheet having slits at locations corresponding to locations of the heat dissipation surface wires to the heat dissipation surface as the TIM.

19. The method of manufacturing the semiconductor device according to claim 18, wherein
a thickness of the heat dissipation sheet attached to the heat dissipation surface in the step (c) is greater than an amount of protrusion of the heat dissipation surface wire from the heat dissipation surface after the step (b).

20. The method of manufacturing the semiconductor device according to claim 14, further comprising the step of
(d) attaching a cooler to the heat dissipation surface via the heat dissipation surface wires and the TIM.
